(19) United States
(12) Patent Application Publication
(10) Pub. No.: US 2026/0096308 A1
(43) Pub. Date: Apr. 2, 2026

(54) DISPLAY PANEL

(71) Applicant: HKC CORPORATION LIMITED, SHENZHEN (CN)

(72) Inventors: Dongmei WEI, SHENZHEN (CN); Zhonglin CAO, SHENZHEN (CN); Lidan YE, SHENZHEN (CN)

(73) Assignee: HKC CORPORATION LIMITED, SHENZHEN (CN)

(21) Appl. No.: 19/321,242

(22) Filed: Sep. 7, 2025

(30) Foreign Application Priority Data
Sep. 30, 2024 (CN) 202411391095.4

(51) Int. Cl. H10K 59/124; H10K 59/123

(52) U.S. Cl. CPC H10K 59/124; H10K 59/123

(57) ABSTRACT

The present application provides a display panel. The display panel may include a glass substrate, a plurality of light-emitting units, a plurality of first bonding portions, a silicon-based driving substrate, an insulating layer and a protective layer. The glass substrate may define a plurality of conductive vias. The plurality of conductive vias may include a plurality of conductive vias. The first bonding portion may be electrically connected to the matched anode electrode through the matched first conductive via. The silicon-based driving substrate may include a plurality of first bonding electrodes. The insulating layer may include a first engaging portion. The protective layer may include a second engaging portion. One of the first engaging portion and the second engaging portion may be a recess structure, and another may be a protruding structure. The protruding structure may be embedded in the recess structure.

### CROSS REFERENCE TO RELATED APPLICATIONS

This application claims priority to Chinese Patent Application No. 202411391095.4, entitled “display panel”, filed on Sep. 30, 2024, which is herein incorporated by reference in its entirety.

### TECHNICAL FIELD

The present disclosure relates to the field of display technologies, and in particular to a display panel.

### BACKGROUND

A monocrystalline silicon driving backplane is a driving substrate formed with semiconductor devices as driving units, and the semiconductor devices are fabricated by complementary metal oxide semiconductor (CMOS) process. Compared with conventional active-matrix organic light-emitting diode (AMOLED) panels that adopt amorphous silicon, micro-crystalline silicon, or low-temperature poly-silicon thin-film transistors as backplanes, the monocrystalline silicon driving backplane may have a much higher carrier mobility. Therefore, the organic light emitting diode (OLED) display panel based on silicon is currently a type of display panel with the best performance in products of augmented reality (AR) and/or virtual reality (VR) fields.

At present, display chips that are traditionally externally bonded are integrated into a silicon-based driving backplane in silicon-based OLED display panels. A preparation method may include fabricating OLED light-emitting devices by evaporation on a silicon-based driving substrate. The specific process may include: first depositing and forming an anode electrode, then fabricating a pixel definition layer, and then depositing an organic light-emitting layer and a cathode electrode in sequence. In this way, pixel units of smaller sizes may be prepared, thereby achieving display fineness beyond a retina level, and pixel units may include many advantages such as high resolution, high integration, low power consumption, small size, and light weight or the like.

However, directly fabricating the OLED light-emitting devices by evaporation on the silicon-based driving substrate may easily affect a silicon-based driving circuit, leading to damage of the driving circuit and making it unusable, which may increase the cost.

### SUMMARY

A technical solution adopted by the present disclosure is to provide a display panel. The display panel may include: a glass substrate, a plurality of light-emitting units, a plurality of first bonding portions, and a silicon-based driving substrate. The glass substrate may include a first surface and a second surface that are opposite to each other. The glass substrate may define a plurality of conductive vias extending from the first surface to the second surface. The plurality of conductive vias may include a plurality of conductive vias. The plurality of light-emitting units may be arranged on the first surface of the glass substrate. The light-emitting unit may include an anode electrode, an organic light-emitting layer, and a cathode electrode that are stacked in sequence in a direction away from the glass substrate. Each of the plurality of first bonding portions may be at least partially arranged in a matched first conductive via. Each of the plurality of first bonding portions may be electrically connected to a matched anode electrode through a matched first conductive via. The silicon-based driving substrate may be arranged on a side of the second surface of the glass substrate. The silicon-based driving substrate may include a plurality of first bonding electrodes. The plurality of first bonding electrodes may be aligned and bonded with the plurality of first bonding portions in one-to-one correspondence. An insulating layer may be arranged on the second surface of the glass substrate. The insulating layer may include a first engaging portion. A protective layer may be arranged on a side of the silicon-based driving substrate close to the glass substrate. The protective layer may include a second engaging portion. One of the first engaging portion and the second engaging portion may be a recess structure, another of the first engaging portion and the second engaging portion may be a protruding structure. The protruding structure may be embedded in the recess structure.

### BRIEF DESCRIPTION OF THE DRAWINGS

FIG. 1 is a schematic structural view of a display panel according to an embodiment of the present disclosure.

FIG. 2 is an enlarged view of a portion in a rectangular A of the display panel in FIG. 1.

FIG. 3 is a schematic exploded view of the structure shown in FIG. 2.

FIG. 4 is a schematic structural view of the insulating layer in FIG. 1.

FIG. 5 is a schematic structural view of the protective layer in FIG. 1.

FIG. 6 is an enlarged view of a portion in a rectangular B of the display panel in FIG. 1.

FIG. 7 is a schematic exploded view of the structure shown in FIG. 6.

### DETAILED DESCRIPTION

Technical solutions in embodiments of the present disclosure will be described clearly and thoroughly in connection with accompanying drawing of the embodiments of the present disclosure. Obviously, the described embodiments are only a part of the embodiments, but not all of them. All other embodiments by a person of ordinary skills in the art based on embodiments of the present disclosure without creative efforts should all be within the protection scope of the present disclosure.

The terms “first”, “second”, and “third” in this disclosure are only for the purpose of description, and cannot be construed as indicating or implying relative importance or implicitly indicating the number of technical features referred to. Therefore, the features defined with “first”, “second”, and “third” may explicitly or implicitly include at least one of the features. In the description of the present disclosure, “a plurality of” means at least two, such as two, three, etc., unless otherwise specifically defined. All directional indicators (such as up, down, left, right, front, back . . . ) in embodiments of the present disclosure are only used to explain a motion state, a relative positional relationship between the components in a specific posture (as shown in the drawings). If the specific posture changes, then the directional indication will change accordingly. In addition, the terms “include”, “comprise” and any variations thereof are intended to cover non-exclusive inclusion. For example, a process, a method, a system, a product, or a device that includes a series of operations or units is not limited to the listed operations or units, but optionally includes unlisted operations or units, or optionally also includes other operations or units inherent to these processes, methods, products or devices.

Reference to “embodiments” herein means that a specific feature, structure, or characteristic described in conjunction with the embodiments may be included in at least one embodiment of the present disclosure. The appearance of this phrase in various locations in the specification does not necessarily refer to the same embodiment, nor is it an independent or alternative embodiment mutually exclusive with other embodiments. Those skilled in the art may explicitly and implicitly understand that, the embodiments described herein may be combined with other embodiments.

The present disclosure will be described in detail below with reference to the drawings and embodiments.

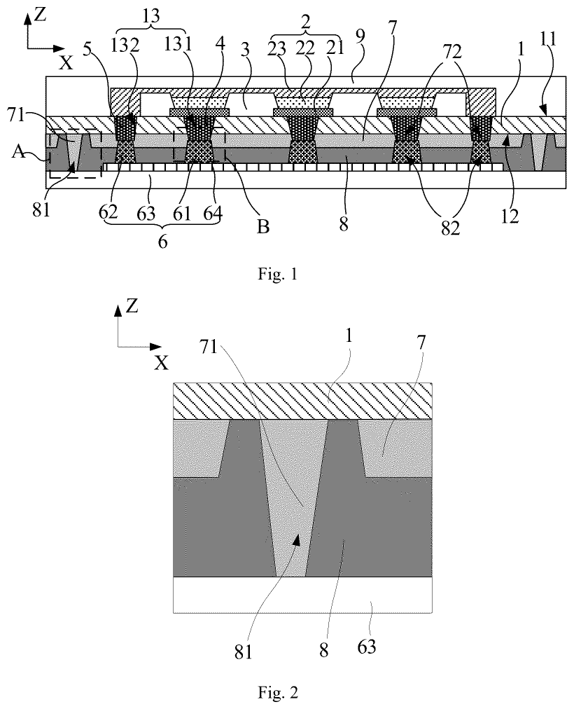

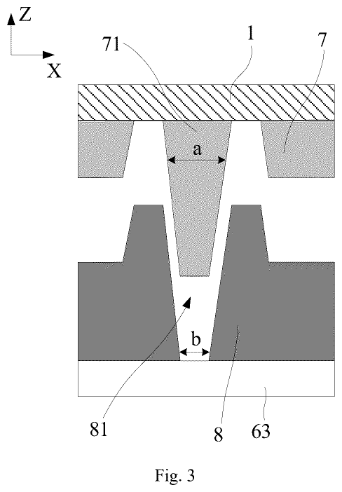

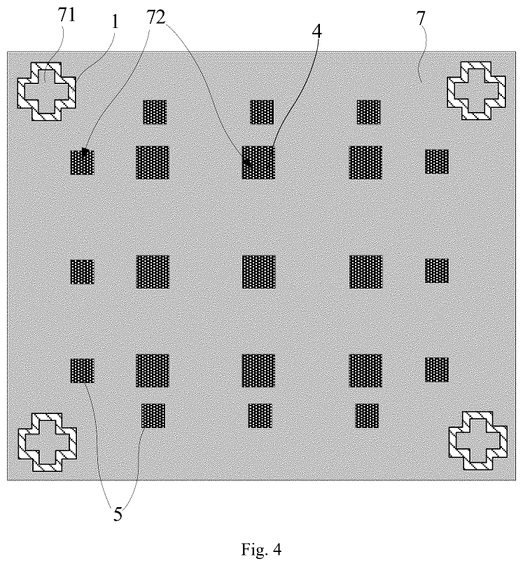

As illustrated in FIG. 1, FIG. 1 is a schematic structural view of a display panel according to an embodiment of the present disclosure. FIG. 2 is an enlarged view of a portion in a rectangular A of the display panel in FIG. 1. FIG. 3 is a schematic exploded view of the structure shown in FIG. 2. The present disclosure provides a display panel. The display panel may be an OLED display panel. The display panel may include a glass substrate 1, a plurality of light-emitting units 2, a plurality of first bonding portions 4, and a silicon-based driving substrate 6.

The glass substrate 1 may include a first surface 11 and a second surface 12 that are opposite to each other. The glass substrate 1 may define a plurality of conductive vias 13 extending from the first surface 11 to the second surface 12. The diameter of the conductive vias 13 may ranges from 50 micrometers to 100 micrometers. If the spacing between adjacent conductive vias 13 is too small, the structural strength of the glass substrate 1 may be affected, and damage to the glass substrate 1 may be caused. If the spacing is too large, the density of the conductive vias 13 may be affected. Therefore, the spacing between adjacent conductive vias 13 may range from 50 micrometers to 150 micrometers. The plurality of conductive vias 13 may include a plurality of first conductive vias 131.

A plurality of light-emitting units 2 may be arranged on the first surface 11 of the glass substrate 1. Each light-emitting unit 2 may include an anode electrode 21, an organic light-emitting layer 22, and a cathode electrode 23 that are stacked in sequence in a direction away from the glass substrate 1. Specifically, a pixel definition layer 3 may also be arranged on the first surface 11 of the glass substrate 1. The pixel definition layer 3 may protrude from the glass substrate 1 and enclose a plurality of pixel accommodation regions (not illustrated in the drawings). The plurality of light-emitting units 2 may be respectively arranged within the plurality of pixel accommodation regions. The plurality of pixel accommodation regions may be arranged in one-to-one correspondence with the plurality of first conductive vias 131.

The anode electrode 21 may be arranged on the surface of the glass substrate 1 exposed through the pixel accommodation region. The pixel definition layer 3 may cover an edge of the anode electrode 21. This is to avoid a contact between the anode electrodes 21 of adjacent light-emitting units 2, which may cause a case of signal crosstalk. The organic light-emitting layer 22 may be arranged on a side surface of the anode electrode 21 away from the glass substrate 1. The cathode electrode 23 may be arranged on a side of the organic light-emitting layer 22 away from the anode electrode 21, and cover the organic light-emitting layers 22 of the plurality of light-emitting units 2, so as to form a full-surface of common cathode. The anode electrode 21 may transmit an anode drive signal to the organic light-emitting layer 22, and the cathode electrode 23 may transmit a cathode drive signal to the organic light-emitting layer 22, so as to drive the organic light-emitting layer 22 to emit light.

In some embodiments, the light-emitting units 2 may include light-emitting units with different emission colors 2, such as red light-emitting units, green light-emitting units, and blue light-emitting units, so as to achieve colorful display. Specifically, the emission color of the light-emitting unit 2 may be determined by the emission color of the organic light-emitting layer 22. Alternatively, in some other embodiments, the light-emitting units 2 may also be light-emitting units of a same color, such as white, red, green, blue, or other colors, which may be specifically set according to actual needs. For example, the light-emitting units 2 may be white, gray-scale display may be achieved by controlling a brightness of the light-emitting units 2. A color resistant layer may also be additionally arranged above the light-emitting units 2 to achieve colorful display. For example, if the light-emitting units 2 are blue, a red quantum dot layer may be additionally arranged above some of the light-emitting units 2, and a green quantum dot layer may be additionally arranged above some of the light-emitting units 2, so as to achieve colorful display.

A plurality of first bonding portions 4 may be arranged on the second surface 12 of the glass substrate 1. Each first bonding portion 4 may be at least partially arranged in a matched first conductive via 131. Each first bonding portion 4 may be electrically connected to the matched anode electrode 21 through the first conductive via 131, so as to transmit an anode driving signal to the anode electrode 21 of the matched light-emitting unit 2 through the first conductive via 131.

The silicon-based driving substrate 6 may be arranged on a side of the second surface 12 of the glass substrate 1. The silicon-based driving substrate 6 may further include a plurality of first bonding electrodes 61. The plurality of first bonding electrode 61 may be aligned and bonded with the plurality of first bonding portion 4 in one-to-one correspondence, and is configured to control the light-emitting unit 2 matching with the first bonding portion 4 to emit light. Specifically, the silicon-based driving substrate 6 may further include a silicon base substrate 63 and a driving circuit 64 arranged in a stacked manner. The silicon base substrate 63 may refer to a base substrate plate based on a monocrystalline silicon material. The driving circuit 64 may be electrically connected to the plurality of first bonding electrodes 61, so as to transmit an anode driving signal to the anode electrode 21 through the first bonding portions 4. Specifically, the driving circuit 64 may include an active driving circuit integrated on the monocrystalline silicon base substrate through a complementary metal-oxide-semiconductor (CMOS) process. The driving circuit 64 may include a plurality of “3T1C” (3 thin-film transistors and 1 capacitor) structure, so as to achieve independent control of each light-emitting unit 2 and a high-quality image display.

The silicon-based driving substrate 6 may further include a display control circuit (not illustrated in the drawings). The display control circuit may be electrically connected to the driving circuit 64. The display control circuit may control the light-emitting units 2 to perform display through the driving circuit 64. The display control circuit may be an integrated circuit (IC) integrated on the silicon-based driving substrate 6.

By arranging the light-emitting units 2 and the first bonding portions 4 on the two opposite surfaces of the glass substrate 1 respectively, the plurality of first bonding portions 4 may be in contact and electrically connected to the anode electrodes 21 of the matched light-emitting units 2 through the conductive vias 131. After the first bonding portions 4 are bonded to the first bonding electrode 61 of the silicon-based driving substrates 6, an electrical coupling between the light-emitting units 2 and the silicon-based driving substrates 6 may be achieved, enabling the silicon-based driving substrates 6 to drive the light-emitting units 2 to emit light. In this way, the light-emitting units 2 may be fabricated on the glass substrate 1 and then bonded to the silicon-based driving substrates 6. There is no need to directly fabricate the light-emitting units 2 on the silicon-based driving substrates 6, the problem of reduced product yield caused by damage to the pixel driving circuit 64 due to directly fabrication of the light-emitting units 2 on the silicon-based driving substrates 6 may be avoided.

A protective layer 8 may be further arranged on a side of the silicon-based driving substrate 6 close to the glass substrate 1. The protective layer 8 may be arranged on a side of the driving circuit 64 away from the silicon base substrate 63, so as to protect the driving circuit 64 and the first bonding electrode 61 from being corroded by external water vapor. A material of the protective layer 8 may be inorganic insulating materials such as silicon dioxide, silicon nitride, or silicon oxynitride. An insulating layer 7 may be further arranged on the second surface 12 of the glass substrate 1, so as to protect the first bonding portion 4 from being corroded by the external water vapor. A surface of the insulating layer 7 away from the glass substrate 1 may be attached to a side surface of the protective layer 8 away from the silicon base substrate 63.

As illustrated in FIG. 2, the insulating layer 7 may include a first engaging portion 71, and the protective layer 8 may include a second engaging portion 81. One of the first engaging portion 71 and the second engaging portion 81 may be a recess structure or a concave structure, and another of the first engaging portion 71 and the second engaging portion 81 may be a protruding structure or a convex structure. The protruding structure may be embedded in or inserted into the recess structure. In the present embodiment, the first engaging portion 71 of the insulating layer 7 may be a protruding structure, and the second engaging portion 81 of the protective layer 8 may be a recess structure. The first engaging portion 71 may be embedded in the second engaging portion 81. In this way, the insulating layer 7 and the protective layer 8 may be accurately aligned, such that each first bonding portion 4 may be accurately bonded to the matched first bonding electrode 61.

By arranging the insulating layer 7 and the protective layer 8 between the glass substrate 1 and the silicon-based driving substrate 6, a case in which the first bonding portion 4 and the first bonding electrode 61 are directly exposed and corroded by the water vapor after bonding together, resulting in poor display, may be avoided. Further, by providing the protruding structure in one of the insulating layer 7 and the protective layer 8, defining the recess structure in another of the insulating layer 7 and the protective layer 8, and embedding the protruding structure in the recess structure during a bonding process, a bonding accuracy may be increased. A case in which a bonding deviation affects a contact resistance and leads to signal loss may be avoided. In addition, the embedding fit between the insulating layer 7 and the protective layer 8 may also avoid a displacement of the glass substrate 1 relative to the silicon-based driving substrate 6. This displacement may affect the contact resistance.

The following embodiments of the present disclosure are all described by taking the first engaging portion 71 as a protruding structure and the second engaging portion 81 as a recess structure as an example.

As illustrated in FIG. 2, in some embodiments, an end of the first engaging portion 71 far away from the glass substrate 1 may protrude from a horizontal plane where the insulating layer 7 is attached to the protective layer 8, so as to form the protruding structure. The second engaging portion 81 may be recessed from the horizontal plane where the insulating layer 7 is attached to the protective layer 8, towards the silicon-based driving substrate 6, so as to define the recess structure.

As illustrated in FIG. 3, in some embodiments, a width a of the protruding structure may gradually decrease along a direction approaching the recess structure. In other words, along a direction from the glass substrate 1 to the silicon-based driving substrate 6, the width of the first engaging portion 71 may gradually decrease, so that the protruding structure may form a convex with a large tip and a small base. The width b of the recess structure may gradually increase along a direction approaching the protruding structure. In other words, along a direction from the silicon-based driving substrate 6 to the glass substrate 1, a width of the second engaging portion 81 may gradually increase, so that the recess structure may form an open-mouthed-type groove, facilitating alignment and embedding of the protruding structure. The width a of the protruding structure may be the size of the protruding structure along a direction perpendicular to the glass substrate 1. The width b of the recess structure may be the size of the recess structure along a direction perpendicular to the glass substrate 1.

Specifically, along a direction perpendicular to the glass substrate 1, a cross-section of the protruding structure and a cross-section of the recess structure may both be trapezoidal, thereby facilitate the mutual embedding of the first engaging portion 71 and the second engaging portion 81. Specifically, as illustrated in FIG. 2, the cross-section of the first engaging portion 71 along a stacking direction Z may be an inverted trapezoid. A length of a top edge of the cross-section of the first engaging portion 71 close to the glass substrate 1 may be greater than a length of a bottom edge close to the silicon-based driving substrate 6. Correspondingly, the cross-section of the second engaging portion 81 along the stacking direction Z may also be trapezoidal. A length of a top edge of the cross-section of the second engaging portion 81 close to the glass substrate 1 may be greater than a length of a bottom edge close to the silicon-based driving substrate 6.

Further, along a direction parallel to the glass substrate 1, the cross-sections of the protruding structure and the recess structure may both be cross-shaped. In this way, after the first engaging portion 71 and the second engaging portion 81 are mutually embedded, the glass substrate 1 and the silicon-based driving substrate 6 may be better fixed, thereby avoiding a relative displacement of the glass substrate 1 and the silicon-based driving substrate 6 in a plurality of directions parallel to the display panel.

As illustrated in FIG. 2, in a specific embodiment, along a direction parallel to the glass substrate 1, the side walls of the protruding structure may respectively abut against the side walls of the recess structure. In this way, after the silicon-based driving substrate 6 is bonded to the glass substrate 1, the side walls of the first engaging portion 71 may be closely attached to the inner side walls of the second engaging portion 81, thereby further avoiding the relative displacement of the glass substrate 1 and the silicon-based driving substrate 6 in a direction parallel to the display panel. At the same time, it may also avoid a case in which the external water vapor enters the display panel through a gap between the first engaging portion 71 and the second engaging portion 81 to corrode internal devices.

Further, the top wall of the protruding structure may abut against the bottom wall of the recess structure, such that the top wall of the first engaging portion 71 may closely attach the bottom wall of the second engaging portion 81. This may further avoid the case in which the external water vapor enters the display panel through a gap between the first engaging portion 71 and the second engaging portion 81 to corrode internal devices.

Further, along the stacking direction Z, both ends of the protruding structure may respectively abut against the glass substrate 1 and the silicon-based driving substrate 6, and both ends of the sidewall of the recess structure may respectively abut against the glass substrate 1 and the silicon-based driving substrate 6. In this way, the first engaging portion 71 of the insulating layer 7 may be allowed to be fully embedded within the second engaging portion 81 of the protective layer 8, thereby better fixing relative positions of the glass substrate 1 and the silicon-based driving substrate 6 along the direction parallel to the display panel.

In some embodiments, as illustrated in FIG. 1, a projection of the driving circuit 64 onto the silicon base substrate 63 along the stacking direction Z may be located within the silicon base substrate 63, thereby exposing a circumferential edge of the silicon base substrate 63. The protective layer 8 may cover a surface of the driving circuit 64, and may cover a surface of the exposed circumferential edge of the silicon base substrate 63. The first engaging portion 71 may be arranged at a location of the insulating layer 7 matching with the circumferential edge of the silicon base substrate 63, and the second engaging portion 81 may also be arranged at a location of the protective layer 8 matching with the circumferential edge of the silicon base substrate 63.

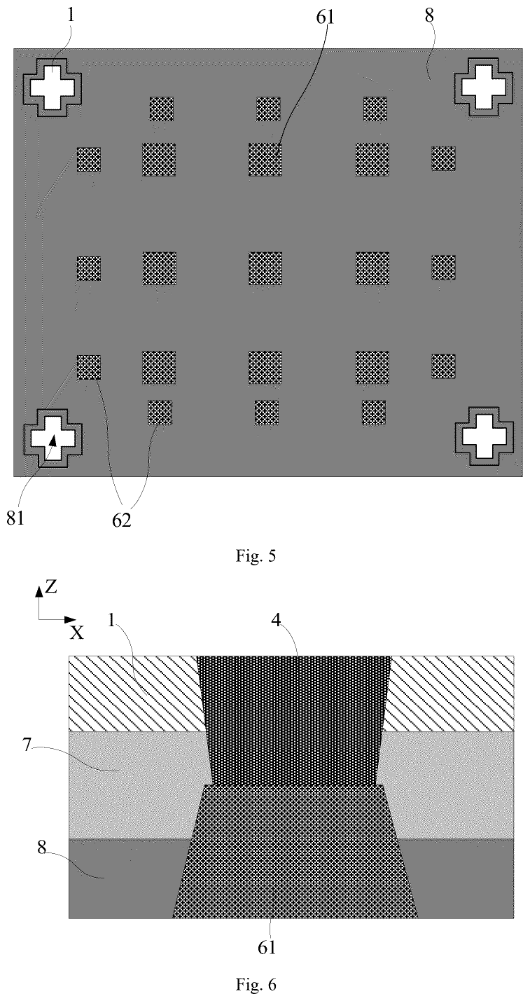

In some embodiments, as illustrated in FIG. 4 and FIG. 5, FIG. 4 is a schematic structural view of the insulating layer in FIG. 1. FIG. 5 is a schematic structural view of the protective layer in FIG. 1. As illustrated in FIG. 2, FIG. 3, and FIG. 4, the first engaging portion 71 may extend towards the silicon-based driving substrate 6 along the stacking direction Z until to the surface of the silicon base substrate 63. A portion of the insulating layer 7 at both sides of the first engaging portion 71 may be recessed towards the glass substrate 1, thereby defining a groove surrounding the first engaging portion 71. As illustrated in FIG. 2, FIG. 3, and FIG. 5, correspondingly, the sidewall of the second engaging portion 81 may extend towards the glass substrate 1 to the second surface 12 of the glass substrate 1, so as to form a protrusion. The protrusion may enclose and define a recess structure that penetrates through the insulating layer 7 and the protective layer 8. The first engaging portion 71 may be embedded within the second engaging portion 81. The protrusion surrounding the second engaging portion 81 may be embedded within the groove surrounding the first engaging portion 71, thereby better fixing relative positions of the glass substrate 1 and the silicon-based driving substrate 6 along the direction parallel to the display panel.

The number of the first engaging portions 71 may be plural. The plurality of first engaging portions 71 may be arranged at intervals along the circumferential edge of the insulating layer 7. The number of the second engaging portions 81 may also be plural. The plurality of second engaging portions 81 may be arranged at intervals along the circumferential edge of the protective layer 8. The plurality of first engaging portions 71 and the plurality of second engaging portions 81 may be embedded in one-to-one correspondence, further increasing the bonding accuracy and preventing a bonding deviation that may affect the contact resistance and leading to the issue of signal loss. In addition, this may further prevent relative displacement between the glass substrate 1 and the silicon-based driving substrate 6.

Specifically, the number of first engaging portions 71 may be four, and the four first engaging portions 71 may be respectively arranged at four corners of the insulating layer 7. The number of second engaging portions 81 may also be four, and the four second engaging portions 81 may be respectively arranged at the four corners of the protective layer 8. Of course, in some other embodiments, the plurality of first engaging portions 71 may also be arranged at other locations of the circumferential edge of the insulating layer 7. For example, the first engaging portions 71 may be arranged at middle locations of the four edges of the insulating layer 7. The plurality of second engaging portions 81 may be arranged at locations matching the circumferential edges of the protective layer 8.

As illustrated in FIG. 1, in some embodiments, the conductive via 13 may further include a plurality of second conductive vias 132 arranged around a peripheral outer side of the plurality of first conductive vias 131. The display panel may further include a plurality of second bonding portions 5 which are at least partially arranged within the second conductive vias 132. Each second bonding portion 5 may be electrically connected to the cathode electrode 23 through the matched second conductive via 132, so as to transmit a cathode driving signal to the cathode electrode 23 of the light-emitting unit 2 through the second conductive via 132. The silicon-based driving substrate 6 may further include a plurality of second bonding electrodes 62. Each second bonding electrodes 62 may be aligned and bonded with the plurality of second bonding portions 5 in one-to-one correspondence. The silicon-based driving substrate 6 can transmit a cathode driving signal to the cathode electrode 23 through the second bonding electrodes 62 and the second bonding portions 5, so as to control the light-emitting units 2 to emit light.

The protective layer 8 may further define a plurality of first through-holes 82. Both the first bonding electrode 61 and the second bonding electrode 62 may be embedded within the first through-holes 82 and electrically connected to the driving circuit 64. Specifically, the plurality of first through-holes 82 may be defined in one-to-one correspondence with the plurality of first conductive vias 131 and the plurality of second conductive vias 132 respectively. Each first through-hole 82 may extend through the protective layer 8 along the stacking direction Z. The first bonding electrodes 61 may be arranged within a portion of the first through-holes 82 matching with the first conductive vias 131, so as to electrically connect the driving circuit 64 to the first bonding portions 4. The second bonding electrodes 62 may be arranged within a portion of the first through-holes 82 matching with the second conductive vias 132, so as to electrically connect the driving circuit 64 to the second bonding portions 5.

The insulating layer 7 may define a plurality of second through-holes 72 at locations matching with the first conductive vias 131 and the second conductive vias 132. The second through-hole 72 may extend through the insulating layer 7 along the stacking direction Z. The first bonding portions 4 and the second bonding portions 5 may all be embedded within the matched second through-holes 72. Specifically, a portion of the first bonding portion 4 close to the anode electrode 21 may be embedded within the first conductive via 131 and contact the cathode electrode 21. A portion of the first bonding portion 4 close to the first bonding electrode 61 may be embedded within a portion of the second through-holes 72 matching with the first conductive via 131, and contact the first bonding electrode 61, thereby electrically connecting the first bonding electrode 61 to the anode electrode 21. A portion of the second bonding portion 5 close to the cathode electrode 23 may be embedded within the second conductive via 132 and contact the cathode electrode 23. A portion of the second bonding portion 5 close to the second bonding electrode 62 may be embedded within a portion of the second through-holes 72 matching with the second conductive via 132 and contact the second bonding electrode 62, thereby electrically connecting the second bonding electrode 62 to the cathode electrode 23.

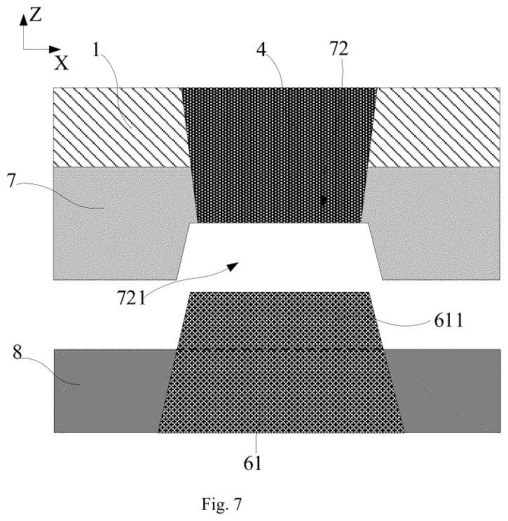

As illustrated in FIG. 6 and FIG. 7, FIG. 6 is an enlarged view of a portion in a rectangular B of the display panel in FIG. 1. FIG. 7 is a schematic exploded view of the structure shown in FIG. 6. Further, a surface of the first bonding portion 4 away from the glass substrate 1 may be lower than a surface of the insulating layer 7 away from the glass substrate 1, such that the first bonding portion 4 and the second through-hole 72 may form a groove portion 721. A surface of the first bonding electrode 61 away from the silicon base substrate 63 may protrude beyond a surface of the protective layer 8 away from the silicon base substrate 63, such that a portion of the first bonding electrode 61 protruding beyond the protective layer 8 may form a protruding portion 611. Thus, when the first bonding electrode 61 is bonded to the first bonding portion 4, the protruding portion 611 may be embedded within the groove portion 721, so as to achieve alignment. This may provide a guiding effect during alignment, further improving alignment accuracy. Additionally, a position of the first bonding electrode 61 may be limited, further preventing issues such as displacement after the alignment process.

Specifically, for the portion of the first bonding portion 4 embedded within the second through-hole 72, a height of this portion along the stacking direction Z may be less than a depth of the second through-hole 72 along the stacking direction Z. A side surface of the first bonding portion 4 away from the glass substrate 1 may form a bottom wall of the groove portion 721. A portion of the insulating layer 7 within the second through-hole 72 and away from the glass substrate 1 may form the sidewall of the groove portion 721. A height of the first bonding electrode 61 along the stacking direction Z may be greater than the depth of the first through-hole 82 along the stacking direction Z.

In a specific embodiment, a surface of the second bonding portion 5 away from the glass substrate 1 may be lower than the surface of the insulating layer 7 away from the glass substrate 1, such that the second bonding portion 5 and the second through-hole 72 may form the groove portion 721. A surface of the second bonding electrode 62 away from the silicon base substrate 63 may protrude beyond the surface of the protective layer 8 away from the silicon base substrate 63, such that a portion of the second bonding electrode 62 protruding beyond the protective layer 8 may form the protruding portion 611. Thus, when the second bonding electrode 62 is bonded to the second bonding portion 5, the protruding portion 611 may be embedded within the groove portion 721, further improving alignment accuracy and preventing issues such as displacement after alignment.

As illustrated in FIG. 1, in some embodiments, an encapsulation layer may be further arranged on the glass substrate 1. The encapsulation layer 30 may be configured to protect the light-emitting units 2 of the glass substrate 1, isolate external water and oxygen, and prevent the light-emitting units 2 from failing due to water and oxygen intrusion. Specifically, the encapsulation layer may cover a side surface of the cathode electrode 23 away from the anode electrode 21. The encapsulation layer 24 may be engaged on the surface of the glass substrate 1 not covered by the light-emitting units 2.

The embodiments of the present disclosure may provide the display panel. The display panel may include a glass substrate 1, a plurality of light-emitting units 2, a plurality of first bonding portions 4, and a silicon-based driving substrate 6. The glass substrate 1 may include the first surface 11 and the second surface 12 that are opposite to each other. The glass substrate 1 may define a plurality of conductive vias 13 extending from the first surface 11 to the second surface 12. The plurality of conductive vias 13 may include a plurality of first conductive vias 131. The plurality of light-emitting units 2 may be arranged on the first surface 11 of the glass substrate 1. Each light-emitting unit 2 may include the anode electrode 21, the organic light-emitting layer 22, and the cathode electrode 23 that are stacked in sequence in the direction away from the glass substrate 1. Each first bonding portion 4 may be at least partially arranged in the matched first conductive via 131. The first bonding portion 4 may be electrically connected to the matched anode electrode 21 through the matched first conductive via 131. The silicon-based driving substrate 6 may be arranged on a side of the second surface 12 of the glass substrate 1. The silicon-based driving substrate 6 may include a plurality of first bonding electrodes 61. The plurality of first bonding electrodes 61 may be aligned and bonded with the plurality of first bonding portions 4 in one-to-one correspondence. The insulating layer 7 may be arranged on the second surface 12 of the glass substrate 1. The insulating layer 7 may include the first engaging portion 71. The protective layer 8 may be arranged on the side of the silicon-based driving substrate 6 close to the glass substrate 1. The protective layer 8 may include the second engaging portion 81. One of the first engaging portion 71 and the second engaging portion 81 may be the recess structure, and another of the first engaging portion 71 and the second engaging portion 81 may be the protruding structure. The protruding structure may be embedded in or inserted into the recess structure. By arranging the light-emitting units 2 and the first bonding portions 4 on the two opposite surfaces of the glass substrate 1 respectively, the plurality of first bonding portions 4 may be in contact and electrically connected to the anode electrodes 21 of the matched light-emitting units 2 through the conductive vias 131. After the first bonding portions 4 are bonded to the first bonding electrode 61 of the silicon-based driving substrates 6, an electrical coupling between the light-emitting units 2 and the silicon-based driving substrates 6 may be achieved, enabling the silicon-based driving substrates 6 to drive the light-emitting units 2 to emit light. In this way, the light-emitting units 2 may be fabricated on the glass substrate 1 and then bonded to the silicon-based driving substrates 6. There is no need to directly fabricate the light-emitting units 2 on the silicon-based driving substrates 6, the problem of reduced product yield caused by damage to the pixel driving circuit 64 due to directly fabrication of the light-emitting units 2 on the silicon-based driving substrates 6 may be avoided. By arranging the insulating layer 7 and the protective layer 8 between the glass substrate 1 and the silicon-based driving substrate 6, a case in which the first bonding portion 4 and the first bonding electrode 61 are directly exposed and corroded by the water vapor after bonding together, resulting in poor display, may be avoided. Further, by providing the protruding structure in one of the insulating layer 7 and the protective layer 8, defining the recess structure in another of the insulating layer 7 and the protective layer 8, and embedding the protruding structure in the recess structure during the bonding process, the bonding accuracy may be increased. A case in which the bonding deviation affects the contact resistance and leads to signal loss may be avoided. In addition, the embedding fit between the insulating layer 7 and the protective layer 8 may also avoid the displacement of the glass substrate 1 relative to the silicon-based driving substrate 6. This displacement may affect the contact resistance.

The above are only implementations of the present disclosure, and do not limit the patent scope of the present disclosure. Any equivalent changes to the structure or processes made by the description and drawings of this application or directly or indirectly used in other related technical field are included in the protection scope of this application.

1. A display panel, comprising:
a glass substrate, comprising a first surface and a second surface that are opposite to each other; wherein the glass substrate comprises a plurality of conductive vias extending from the first surface to the second surface; the plurality of conductive vias comprise a plurality of first conductive vias;
a plurality of light-emitting units, arranged on the first surface of the glass substrate; wherein each of the plurality of light-emitting units comprises an anode electrode, an organic light-emitting layer, and a cathode electrode that are stacked in sequence in a direction away from the glass substrate;
a plurality of first bonding portions, wherein each of the plurality of first bonding portions is at least partially arranged in a matched first conductive via; each of the plurality of first bonding portions is electrically connected to a matched anode electrode through a matched first conductive via; and
a silicon-based driving substrate, arranged on a side of the second surface of the glass substrate, and comprising a plurality of first bonding electrodes; wherein the plurality of first bonding electrodes are aligned and bonded with the plurality of first bonding portions in one-to-one correspondence;
wherein an insulating layer is arranged on the second surface of the glass substrate, the insulating layer comprises a first engaging portion; a protective layer is arranged on a side of the silicon-based driving substrate close to the glass substrate, the protective layer comprises a second engaging portion; one of the first engaging portion and the second engaging portion is a recess structure, another of the first engaging portion and the second engaging portion is a protruding structure; the protruding structure is embedded in the recess structure.

2. The display panel as claimed in claim 1, wherein
a width of the protruding structure gradually decreases along a direction approaching the recess structure; a width of the recess structure gradually increases along a direction approaching the protruding structure;
the width of the protruding structure is a size of the protruding structure along a direction perpendicular to the glass substrate; the width of the recess structure is a size of the recess structure along a direction perpendicular to the glass substrate.

3. The display panel as claimed in claim 2, wherein
along the direction perpendicular to the glass substrate, cross-sections of the protruding structure and the recess structure are each trapezoidal.

4. The display panel as claimed in claim 3, wherein
along a direction parallel to the glass substrate, cross-sections of the protruding structure and the recess structure are each cross-shaped.

5. The display panel as claimed in claim 4, wherein
along the direction parallel to the glass substrate, sidewalls of the protruding structure abut against sidewalls of the recess structure respectively;
a top wall of the protruding structure abuts against a bottom wall of the recess structure.

6. The display panel as claimed in claim 5, wherein
along a stacking direction of the display panel, both ends of the protruding structure abut against the glass substrate and the silicon-based driving substrate respectively; both ends of a sidewall of the recess structure abut against the glass substrate and the silicon-based driving substrate respectively.

7. The display panel as claimed in claim 1, wherein
the number of the first engaging portions is plural, the plurality of first engaging portions are arranged at intervals along a circumferential edge of the insulating layer; the number of the second engaging portions is plural, the plurality of second engaging portions are arranged at intervals along a circumferential edge of the protective layer; the plurality of first engaging portions and the plurality of second engaging portions are embedded in one-to-one correspondence.

8. The display panel as claimed in claim 1, wherein
the conductive vias further comprise a plurality of second conductive vias; the display panel further comprises a plurality of second bonding portions at least partially arranged within the matched second conductive vias; the second bonding portion is electrically connected to the cathode electrode through the matched second conductive via;
the silicon-based driving substrate further comprises a plurality of second bonding electrodes, the plurality of second bonding electrodes are aligned and bonded with the plurality of second bonding portions in one-to-one correspondence.

9. The display panel as claimed in claim 8, wherein
the silicon-based driving substrate comprises a silicon base substrate and a driving circuit, the driving circuit is arranged on the silicon base substrate; the protective layer covers the driving circuit;
the protective layer defines a first through-hole; both the first bonding electrode and the second bonding electrode are embedded within the first through-hole and electrically connected to the driving circuit;
the insulating layer defines a second through-hole; both the first bonding portion and the second bonding portion are embedded within the second through-hole.

10. The display panel as claimed in claim 9, wherein
a surface of the first bonding portion and/or the second bonding portion away from the glass substrate is lower than a surface of the insulating layer away from the glass substrate, defining a groove portion;
a surface of the first bonding electrode and/or the second bonding electrode away from the silicon base substrate protrudes beyond a surface of the protective layer away from the silicon base substrate, forming a protruding portion; the protruding portion is embedded within a matched groove portion.
